(19) United States
(12) Patent Application Publication
(10) Pub. No.: US 2008/0263427 A1
(43) Pub. Date: Oct. 23, 2008

(54) System and Method for Optical Disc Encoding/Decoding

(75) Inventors: Arnaud Charles Badey, Southampton (GB); Peter Kollig, Southampton (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/092,117

(22) PCT Filed: Oct. 27, 2006
(86) PCT No.: PCT/IB2006/053971

§ 371 Date: Apr. 30, 2008

(30) Foreign Application Priority Data
Oct. 31, 2005 (EP) 05110185.5
Oct. 27, 2006 (IB) PCT/IB2006/053971

(51) Int. Cl. H03M 13/05; G06F 11/10

(52) U.S. Cl. 714/758; 714/763; 714/E11.032

(57) ABSTRACT

The invention provides for an optical disc encoding and decoding system in which in an encode mode the system is arranged to encode Long Distance Code (LDC) clusters from user data and including error correction means for applying error correction to LDC blocks, and interleaving means arranged to form the LDC clusters by interleaving the LDC blocks, wherein the error correction means comprises a plurality of buffers at least one of which is arranged to retrieve data from a SDRAM of the system and to calculate syndromes and at least another of which is arranged to insert parity bytes in the data prior to return to the SDRAM and wherein while the said another of which buffers stores data and calculates syndromes, the said one of which buffers is arranged to insert parity bytes into the data it previously stored, the interleaving means comprising a plurality of buffers arranged for burst access for retrieving data from the SDRAM of the system.

The present invention relates to a method and system for optical disc encoding/decoding.

The ongoing development of standards relating to optical storage media has lead to the development of so-called Blu-ray Disc (BD) as the next generation replacement for the DVD optical standard. As its name suggests, the BD standard employs laser light within the blue part of the spectrum within the optical pickup unit

which, in view of its shorter wavelength than the red laser light employed within the DVD standard, allows for finer focusing of the laser beam and thus the storage, and retrieval, of ever greater densities of data on an optical disc.

As with the DVD standard, BD employs a cross-interleaved Reed-Solomon code but with an increased Error Correction Code (ECC) block size of 64 kBytes.

In view of this, and in order to perform all of the required error-corrections within the channel codec domain of BD system, it is required that at least two such ECC 64 kByte blocks are stored on-chip within the system. This requirement arises since the error detection/correction based on outer parity bytes can only be executed once an entire ECC block has been received. One data buffer is then employed during accumulation of the incoming data and the related inner parity corrections, whereas a second buffer is employed to perform the outer parity error correction. Of course, additional smaller buffers may be required in order to buffer the incoming data stream until sufficient data has been transferred from one of the main buffers into the SDRAM which is attached to the System on Chip (SOC).

As a result, it will be appreciated that within such an arrangement at least 128 kBytes of on-chip storage is required and this, in turn, can render the SOC prohibitively expensive.

While within the DVD domain various schemes are known that remove the requirement for such large on-chip memories such as the system one of which is disclosed in U.S. Pat. No. 6,877,126, such schemes involve the application of outer parity corrections to the external SDRAM.

Although it is considered that a similar approach could be employed for the BD specification, this would require a significant amount of SDRAM bandwidth which, in turn, would require adoption of Double Data Rate (DDR) devices rather than far more cost effective SDRAM devices.

The present invention therefore seeks to provide for an optical disc encoding/decoding system and method which can offer advantages over known such systems and methods.

In particular, the invention seeks to provide for such a system and method which limits the need to store uncorrected data blocks on-chip and, in turn, to store partially corrected data in an external SDRAM memory so as to allow for execution of corrections at a later point in time.

According to a first aspect of the present invention there is provided an optical disc encoding system arranged to encode LDC clusters from user data and including error correction means for applying error correction in relation to LDC blocks, and interleaving means arranged to form the LDC clusters from the LDC blocks, wherein the error correction means comprises a plurality of buffers one of which is arranged to retrieve data from a SDRAM of the system and to calculate syndromes, while another of which is arranged to insert parity bytes in the data prior to return to the SDRAM and wherein while the said another of which buffers stores data and calculates syndromes, the said one of which buffers is arranged to insert parity bytes into the data previously stored, the interleaving means comprising a plurality of buffers arranged for burst access for retrieving data from the SDRAM of the system.

The invention is advantageous in that through the manner of integration of the interleaving means and the error correction means stated above, it becomes advantageously possible to not only minimise the amount of required on-chip memory, but also to optimise the required SDRAM bandwidth.

On this basis, it then becomes readily possible to employ cost effective SDRAM memories within an encoding system and even for the highest required BD speeds. This advantageously eliminates the need for adopting relatively expensive DDR devices. Also, the bandwidth required to encode or decode a cluster is independent of the number of corrections that need to be applied.

Preferably, the correction means of the system is arranged such that data is retrieved from the SDRAM in the order of a data frame and returned to the SDRAM in the order of a data block.

Further, interleaving means of the system can be arranged such that the data is retrieved from the SDRAM so as to arrive a buffer of the interleaving means in the order of the LDC block and, is arranged to be delivered from the interleaving means in the order of the LDC cluster.

According to another aspect of the present invention, there is provided an optical disc decoding system arranged to decode LDC clusters, and including the de-interleaving means arranged to form LDC blocks from the LDC clusters, and error correction means arranged for applying error correction in relation to the LDC blocks, wherein the de-interleaving means comprises a plurality of buffers arranged for burst access to transfer the LDC blocks to the SDRAM of the system, and the error correction means comprises a plurality of buffers one of which is arranged to retrieve data from the SDRAM and to calculate syndromes, while another of which is arranged to apply required corrections and deliver the data back to the SDRAM of the system, and wherein while the said another of which buffers stores data and calculates syndromes, the said one of which buffers calculates and applies correction on data previously stored and prior to delivery.

Again, this aspect of the present invention advantageously allows for the optimisation of the required SDRAM bandwidth while, at the same time, minimizing the amount of on-chip memory that would otherwise be required.

Preferably, the error correction means of the system is arranged such that data retrieved from the SDRAM in the order of a data block is returned thereto in the order of a data frame.

Also, the de-interleaving means can be arranged such that data arriving in the buffer thereof is in the order of the LDC cluster, and is subsequently delivered to the SDRAM in the order of an LDC block.

Advantageously, either such system as defined above is arranged such that each buffer of the interleaver/de-interleaver corresponds to one line of the LDC.

Further, the interleaver/de-interleaver, as seen by the SDRAM, can be arranged so as to appear to the SDRAM as a single large buffer.

In one particular embodiment, each of the two buffers of the interleaver/de-interleaver comprise 304 bytes.

Preferably, the number of buffers employed is determined on the basis that the remainder of the total buffer size divided by the SDRAM access burst length is equivalent to zero.

Preferably, the plurality of buffers of the error correction means are arranged to operate simultaneously.

Of course, it should be appreciated that, in many embodiments, the system of the present invention will comprise features of the above-mentioned encoding and decoding systems in combination so as to provide for decoding/encoding blocks that can readily be integrated within a data path channel of a system employed for encoding/decoding optical discs.

According to another aspect of the present invention there is provided an optical disc encoding method for encoding LDC clusters from user data, and including applying error correction in relation to LDC blocks and interleaving the LDC blocks to form the LDC clusters, the method including applying error correction by way of a plurality of buffers and retrieving data from an SDRAM of the system and calculating syndromes by way of one of the said buffers, and inserting parity bytes in the data prior to return to the SDRAM by way of another of the said buffers and wherein while the said another of which buffers stores data and calculates syndromes, the said one of which buffers inserts parity bytes into the data previously stored, and further including interleaving the LDC block by way of a further plurality of buffers arranged for burst access to retrieve data from the SDRAM of the system.

According to a yet further aspect of the present invention there is provided an optical disc decoding method for decoding LDC clusters to form LDC blocks and including applying error correction in relation to the LDC blocks and de-interleaving the LDC clusters to form the LDC blocks, the method including de-interleaving the LDC blocks by way of a plurality of buffers arranged for burst access to deliver data to the SDRAM of the system, and further including the step of applying error correction by way of a plurality of buffers and retrieving data from the SDRAM of the system and calculating syndromes by way of one of the buffers, and applying corrections and delivering the data back to the SDRAM of the system by way of another of the buffers, and wherein while the said another of which buffers stores data and calculates syndromes, the said once of which buffers calculates and applies correction on data previously stored and prior to delivery.

Of course, an optical disc encoding/decoding system can be arranged through the provision of the combination of the method steps outlined above.

The invention is describe further hereinafter, by way of example only, with reference to the accompanying drawings in which:

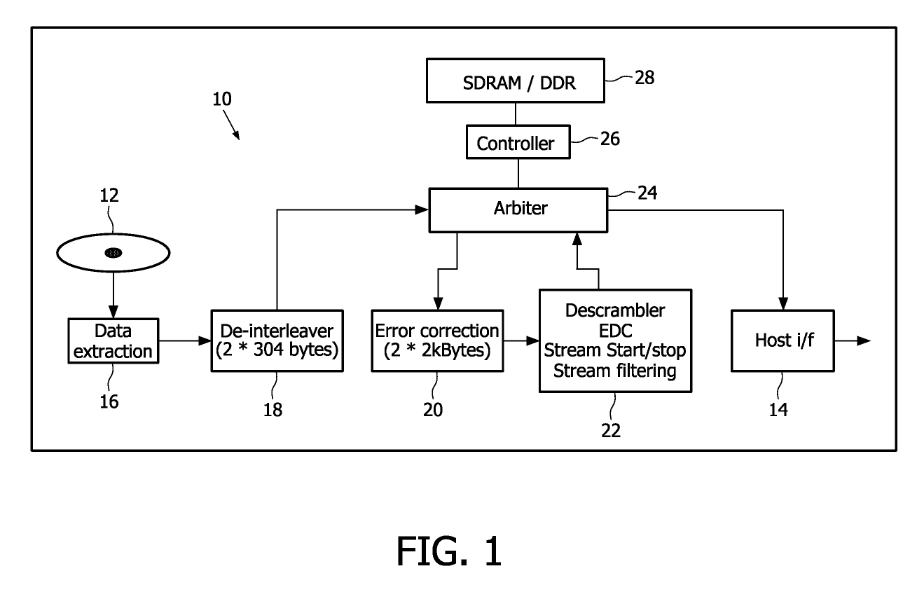

FIG. 1 is a schematic block diagram illustrating the manner in which the functional features of the invention can be integrated within the data path channel of an optical disc encode/decode system;

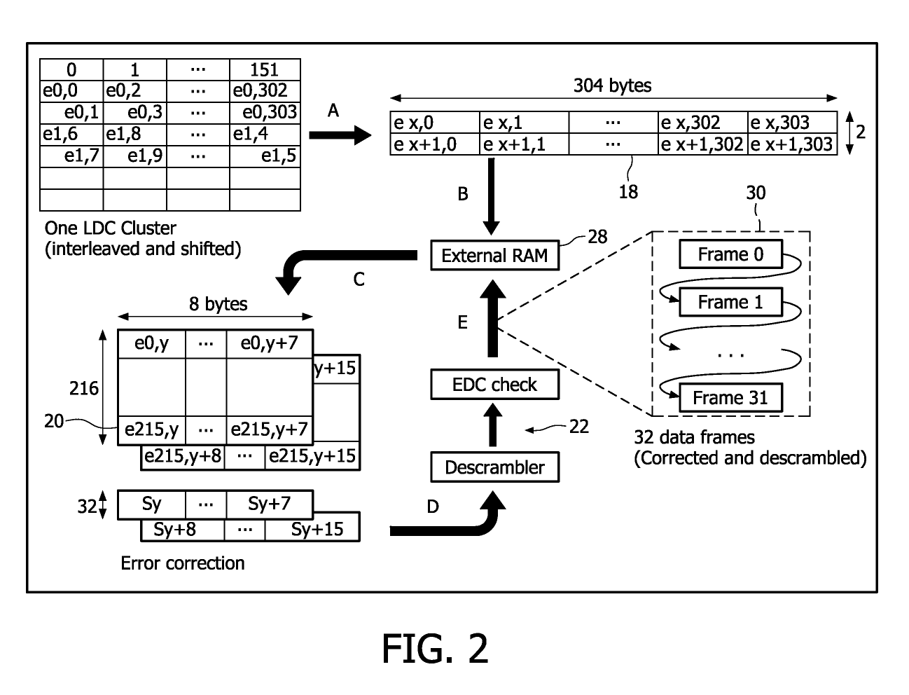

FIG. 2 is a flow diagram illustrating decoding of an optical disc in accordance with an embodiment of the present invention; and

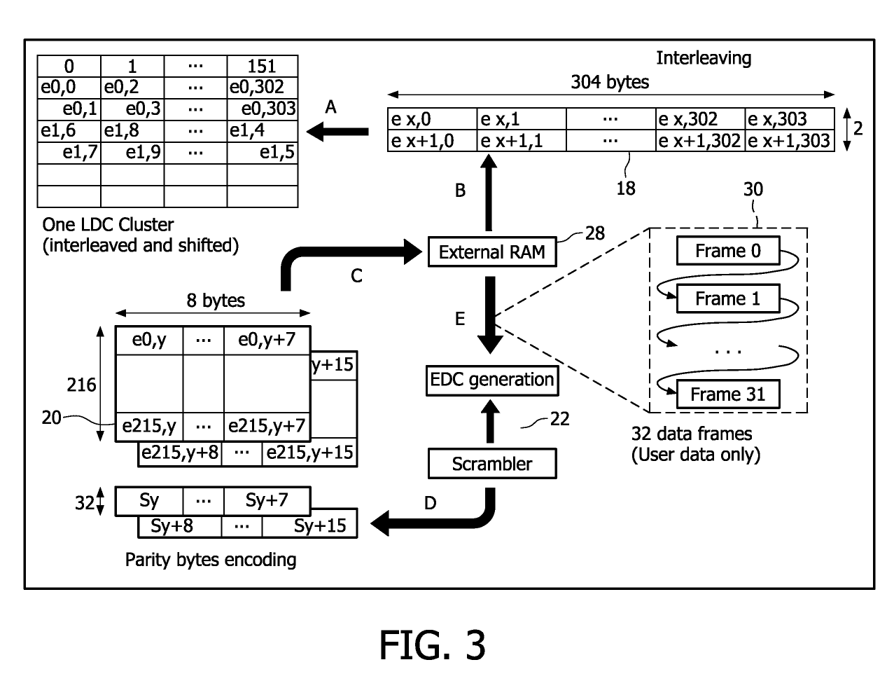

FIG. 3 is a flow diagram illustrating encoding of a disc according to an embodiment of the present invention.

As will be appreciated from the following, the present invention relates to an arrangement and related method for, for example, the encoding/decoding of LDC clusters as defined in BD disc specifications and when transferred to/from user data. As is known LDC clusters comprise interleaved user data and parity bytes and the steps required for the generation of an LDC cluster from user data are outlined below.

First, four bytes of Error Detection Code are generated and added at the end of each of the 32 data frames of the user data and the 32 frames are then scrambled into a block format comprising 32 scrambled data frames stacked horizontally and re-mapped to a block comprising 304 columns by 216 rows. From such a data block, a Long Distance Code (LDC) block is formed comprising the aforementioned data block with the addition of parity bytes such that each column of the data block serves to generate 32 parity bytes.

Subsequently, an LDC cluster is generated from the LDC block through the interleaving of each even numbered column with the column to its right, and then the application of a cyclical shift to each of the rows so that each LDC cluster then comprises 152 columns and 496 rows.

From the above, it will be appreciated that the invention will therefore generally be formed by a series of four functional blocks, the integration of which in accordance with the embodiment of the present invention is illustrated further by reference to FIGS. 1 and 2.

The four functional blocks comprise an interleaver/de-interleaver arranged to generate the above-mentioned LDC block from an LDC cluster when decoding the data, or to generate the LDC cluster from the LDC block when operating in encode mode. Secondly, an error-correction block employing the Reed-Solomon algorithm and which serves to correct the data contained in the LDC block and based on the embedded parity bytes from decode mode, or, alternatively, arranged to calculate the parity bytes in encode mode. Also, a scrambler block is provided for scrambling the user data in encode mode to generate a data block, or to de-scramble a data block in decode mode so as to retrieve the data frames. Finally, an Error Detection Code calculation unit is provided which, in encode mode, serves to generate the four EDC bytes contained in each data frame, but while in decode mode serves to verify the integrity of the data contained in the data frame against EDC bytes.

Of course, additional functional blocks can be added to perform further operations on the data such as for example stream start/stop and stream filtering etc.

As mentioned, these functional blocks are typically integrated within the data path channel of a system employed to encode or decode optical discs and the way in which the blocks are integrated within the data path channel comprises a particular feature of the present invention.

Turning first to FIG. 2, there is illustrated a data path channel 10 of an optical disc encode/decode system arranged for, for example, providing data from an optical disc 12 to a host system interface 14. Data is extracted from, or delivered to, the optical disc 12 by way of a data extraction unit 16 comprising a typical optical pick-up unit and then, by way of the blocks 18-22 found within the data path channel 10, is delivered to, or received from, the host interface 14.

The arrows in FIG. 1, serve to illustrate the direction of data flow when play-back from a disc 12 is occurring, and thereby represents the decoding of the disc.

In accordance with the present invention, burst accesses are employed in order to transfer data to/from the main system memory and the lengths of burst outline below can be selected as required.

As illustrated in FIG. 1, there is provided within the data path 10 an interleaver 18, an error correction unit 20, and de-scrambler/EDC unit 22, and which are arranged to interface with relatively inexpensive SDRAM 28 by way of arbiter unit 24 and associated controller 26.

The interleaver 18 is formed of two buffers each of 304 bytes and, generally, each buffer corresponds to one line of the LDC block. The interleaver is seen by the SDRAM 28 as one large buffer of 604 bytes this serves to allow for data to be transferred to/from the SDRAM in bursts of 32 bytes. That is, nineteen bursts of 32 bytes are employed in order to achieve transfer of 608 bytes. It should of course be appreciated that the interleaver 18 may contain any appropriate number of 304 byte buffers since the number generally depends upon the length of the SDRAM burst access. Generally, the most appropriate number of 304 byte buffers should be such that the remainder of the total buffer size divided by the SDRAM access burst length equals zero. In decode mode, i.e. that illustrated in FIG. 1 by means of the arrows shown, data arrives within each buffer of the de-interleaver 18 in the order of the LDC cluster, i.e. interleaved and shifted, and is then sent to the SDRAM 28 in the order of the LDC block. Alternatively in encode mode data arrives in the buffers of the interleaver 18 in the order of the LDC block and is interleaved and shifted in the buffer in order to be sent out towards the optical disc 12 in the order of the LDC cluster.

The error correction block 20 in the illustrated embodiment comprises two buffers of 8 columns by 248 rows. Each buffer location contains one byte of data and the first 216 rows contain user data, while the last 32 contain the required parity bytes. Advantageously both buffers of the error correction block 20 are employed at the same time. In decode mode, such as that illustrated in FIG. 1, when one buffer receives data from the SDRAM 28 and employs it to calculate the required syndromes, the other of the buffers is employed to apply the corrections and send the data to the SDRAM 28. In that manner, the data arrives from the SDRAM 28 in the order of a data block and then is sent back to the SDRAM 28 in the order of a data frame.

Alternatively, in encode mode, while one buffer of the error correction block 20 retrieves data out of the memory and employs the same to calculate the syndromes, the other of the two buffers is employed to insert the parity bytes and send the data back to the SDRAM 28. In this mode, data arrives back from the memory 28 in the order of a data frame, and is returned to the SDRAM 28 in the order of a data block.

The manner of operation of the buffers employed within the error correction block 20 is as follows. In decode mode, and with the first of the, for example two, buffers arranged to receive data and calculate the related syndromes, the second of the two buffers is arranged to calculate and apply appropriate correction to data contained therein and to send out that corrected data. Next, the first of the two buffers is arranged to calculate and apply correction to data that it had previously stored and to dispatch such corrected data. While the said first buffer acts so as to provide such corrected data, the second buffer is arranged to store data and calculate the related syndrome.

Thus, each of the two buffers is arranged to conduct all the required actions, and to operate simultaneously, they are however arranged to operate with a shift of one half of a processing cycle.

The provision of such a half-cycle shift allows for the continuous receipt and sending of data and, of course, a similar principle is applied when in encode operating mode.

As and illustration, and with regard to data sets n−1, n, n+1 and n+2, the operation is as follows.

While the first buffer is arranged to receive data set n and calculate syndromes on that data set n, the second buffer is arranged to apply corrections on data set n−1 and to send out that data set n−1.

Next, while the first buffer applies corrections on data set n and sends out the data set n, the second buffer is arranged to receive data set n+1 and to calculate the syndromes on the data set n+1.

Then, with the first buffer 1 receiving data set n+2 and calculating the syndromes relating to that data set n+2, the second of the two buffers is arranged to apply corrections on the data set n+1 and to send out the data set n+1.

When data is accessed in the order of a data frame, 8-byte bursts are employed corresponding to the length of one line of the buffer. When data is then accessed in the order of the data block, bursts of 32 bytes are employed. Again, the size of the buffers can be altered in order to readily accommodate different burst lengths. However, the ideal size of each buffer should be such that the number of columns corresponds to the burst length, as measured in bytes, when data is accessed in the order of the data frame. Also, the remainder of the total number of bytes in the buffer divided by the burst length, again measured in bytes, when data is accessed in the order of data block should advantageously be zero. Of course, the number of rows should also generally remain as 48.

The particular steps employed within a system provided in the present invention when decoding a disc are illustrated in FIG. 2.

Here, like reference numerals are employed as those found in FIG. 1 and the diagram illustrates the manner in which one LDC cluster is processed so as to provide 32 data frames of corrected in de-scrambled data 30.

As illustrated, data arrives at the de-interleaver 18 in the form of an LDC cluster, i.e. with data shifted and interleaved, in the direction of arrow A. The data is then sent in the direction of arrow B from the de-interleaver 18 into the SDRAM 28 in the form of an LDC block and in a fully de-interleaved format. From the SDRAM 28, the data is then sent in the direction of arrow C to the error correction block 20 within which the buffers of the error correction block are filled row-by-row. Once the data has been corrected, it is then sent out of the error correction block 20 column-by-column, i.e. in data frame order in the direction of arrow D for de-scrambling and checking of the Error Detection Code.

Once de-scrambled and error-checked, the data is delivered in the direction of arrow E to the SDRAM in the data frame format. As mentioned above, additional blocks such as stream start/stop and stream filtering can be added before the data is actually stored. The corrected and de-scrambled data 30, as delivered to the SDRAM 28, is illustrated in FIG. 2.

Turning now to FIG. 3, there are illustrated different steps of a system embodying the present invention when encoding a disc.

Again, like numbered functional blocks are indicated by way of the same number reference numerals as found in FIG. 1.

In this instance however, the process commences with the 32 data frames, comprising user data 30 sent from the SDRAM 28 into the EDC generator and scrambler 22 in the direction of arrow E. The order of the data transferred is the same as in the data frame.

From the scrambler 22, the data passes in the direction of arrow D through parity byte encoder 20 in which the buffers are filled column-by-column, the syndromes calculated as discussed above, and the parity bytes inserted. The data is effectively then sent back to the SDRAM 28 in the direction of arrow C in the order of an LDC block. In this manner, the buffers is emptied row-by-row. From the SDRAM 28, the data is then delivered in the direction of arrow B to the interleaver 18 and once interleaved and shifted, the data is then sent to the remainder of the system in the order of the LDC cluster formed within the interleaver 18.

As will be appreciated, the manner in which the aforementioned LDC blocks are integrated within the data path channel 10 as illustrated in FIG. 1 forms a particularly important aspect of the present invention.

Through the adoption of the present invention, there is no need to employ large memories in the chip to process the decoding/encoding of data and corrections can be applied directly in the error corrector block and do not then need to be stored before they are applied. The bandwidth required for the system SDRAM to encode or decode a LDC cluster is advantageously not then dependent upon the number of corrections that may be required to be applied on the user data. The re-ordering of the data between the data frame format and the data block format, as defined in BD specifications, is achieved solely by means of the access to the main SDRAM. The invention also advantageously allows for the possibility to correct only the data actually required by a user even if a full LDC cluster is read from the disc. The error correction does not have to be performed on the whole cluster but merely on the columns corresponding to the requested data.

Principally, the present invention not only minimises the amount of required on-chip memory, but also optimises the required SDRAM bandwidth such that it proves possible to use cost-effective SDRAM memories even in seeking to operate in accordance with the highest required BD speeds.

It should also be appreciated that the invention is not restricted to the details of the foregoing embodiment. For example, a direct data link can be provided between the interface 14 and the de-scrambler/EDC unit 22 so as to avoid the need to store and retrieve the data in the SDRAM a second time. The SDRAM bandwidth requirement can then advantageously be halved.

1. An optical disc encoding system arranged to encode Long Distance Code (LDC) clusters from user data and including error correction means for applying error correction in relation to LDC blocks, and interleaving means arranged to form the LDC clusters from the LDC blocks, wherein the error correction means comprises a plurality of buffers one of which is arranged to retrieve data from a SDRAM of the system and to calculate syndromes, while another of which is arranged to insert parity bytes in the data prior to return to the SDRAM, and wherein while the said another of which buffers stores data and calculates syndromes, the said one of which buffers is arranged to insert parity bytes into the data previously stored, the interleaving means comprising a plurality of buffers arranged for burst access for retrieving data from the SDRAM of the system.

2. A system as claimed in claim 1, wherein the correction means of the system is arranged such that data is retrieved from the SDRAM in the order of a data frame and returned to the SDRAM in the order of a data block.

3. A system as claimed in claim 1, wherein the interleaving means of the system is arranged such that data retrieved from the SDRAM so as to arrive a buffer of the interleaving means is in the order of the LDC block and, is arranged to be delivered from the interleaving means in the order of the LDC cluster.

4. A system as derived in claim 1, and including a direct data link between the error correction means and an interface of the system.

5. An optical disc decoding system arranged to decode Long Distance Code (LDC) clusters, and including the de-interleaving means arranged to form LDC blocks from the LDC clusters, and error correction means arranged for applying error correction in relation to the LDC blocks, wherein the de-interleaving means comprises a plurality of buffers arranged for burst access to transfer the LDC blocks to the SDRAM of the system, and the error correction means comprises a plurality of buffers one of which is arranged to retrieve data from the SDRAM and to calculate syndromes, while another of which is arranged to apply required corrections and deliver the data back to the SDRAM of the system, and wherein while the said another of which buffers stores data and calculates syndromes, the said one of which buffers calculates and applies correction on data previously stored and prior to delivery.

6. A system as claimed in claim 5, wherein the error correction means of the system is arranged such that data is retrieved from the SDRAM in the order of a data block and is returned thereto in the order of a data frame.

7. A system as claimed in claim 6, wherein the de-interleaving means is arranged such that data arriving in the buffer thereof is in the order of the LDC cluster, and the data subsequently delivered to the SDRAM is in the order of an LDC block.

8. A system as claimed in claim 5, and including a direct data link between the error correction means and an interface of the system.

9. A system as claimed in claim 1 wherein each buffer of the interleaver/de-interleaver corresponds to one line of the LDC.

10. A system as claimed in claim 1 wherein the interleaver/de-interleaver, as seen by the SDRAM, is arranged so as to appear to the SDRAM as a single large buffer.

11. A system as claimed in claim 1 wherein the plurality of buffers of the error correction means are arranged to operate simultaneously.

12. An optical disc encoding/decoding system comprising the systems as claimed in claim 5.

13. An optical disc encoding method for encoding Long Distance Code (LDC) clusters from user data, and including applying error correction in relation to LDC blocks and interleaving the LDC blocks to form the LDC clusters, the method including applying error correction by way of a plurality of buffers and retrieving data from an SDRAM of the system and calculating syndromes by way of one of the said buffers, and inserting parity bytes in the data prior to return to the SDRAM by way of another of the said buffers and wherein while the said another of which buffers stores data and calculates syndromes, the said one of which buffers inserts parity bytes into the data previously stored, and further including interleaving the LDC block by way of a further plurality of buffers arranged for burst access to retrieve data from the SDRAM of the system.

14. A method as claimed in claim 13 such that data is retrieved from the SDRAM in the order of a data frame and returned to the SDRAM in the order of a data block.

15. A method as claimed in claim 13, and including retrieving the data from the SDRAM so as to arrive at a buffer of the interleaving means in the order of the LDC block, and delivering the data from the interleaving means in the order of the LDC cluster.

16. An optical disc decoding method for decoding Long Distance Code (LDC) clusters to form LDC blocks and including applying error correction in relation to the LDC blocks and de-interleaving the LDC clusters to form the LDC blocks, the method including de-interleaving the LDC blocks by way of a plurality of buffers arranged for burst access to deliver data to the SDRAM of the system, and further including the step of applying error correction by way of a plurality of buffers and retrieving data from the SDRAM of the system and calculating syndromes by way of one of the buffers, and applying corrections and delivering the data back to the SDRAM of the system by way of another of the buffers, and wherein while the said another of which buffers stores data and calculates syndromes, the said one of which buffers calculates and applies correction on data previously stored and prior to delivery.

17. A method as claimed in claim 16 where the data is retrieved from the SDRAM in the order of a data block and returned thereto in the order of a data frame.

18. A method as claimed in claim 16, wherein the data arriving in the buffer of the de-interleaving means is in the order of a LDC cluster, and the data subsequently delivered to the SDRAM is in the order of a LDC block.

19. A method as claimed in, claim 13, and including the step of operating the plurality of buffers within the error correction means simultaneously.

20. An optical disc encoding the decoding method comprising the method steps as claimed in claim 16.
